(19) United States
(12) Patent Application Publication
(10) Pub. No.: US 2006/0091496 A1
(43) Pub. Date: May 4, 2006

(54) Metal-insulator-metal device

(75) Inventors: Kurt Ulmer, Corvallis, OR (US); Jian-gang Weng, Corvallis, OR (US); Peter Mardilovich, Corvallis, OR (US); John Christopher Rudin, Bristol (GB)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, LP

(21) Appl. No.: 10/975,951

(22) Filed: Oct. 28, 2004

(51) Int. Cl. H01L 27/082

(52) U.S. Cl. 257/565

(57) ABSTRACT

A metal-insulator-metal device includes a layer having a major dimensional surface. The layer has a first portion having a first boundary, a second metal portion having a second boundary facing the first boundary in a direction parallel to the surface and a non-linear dielectric between the first boundary and the second boundary and having a thickness orthogonal to the surface.

### BACKGROUND

Metal-insulator-metal (MIM) devices may be used in a variety of different applications such as displays. Many processes used to fabricate MIM devices may require multiple processes which are sometimes difficult to control. In many processes, it is also difficult to control and minimize the size of the MIM device. This has resulted in relatively expensive and large MIM devices.

### BRIEF DESCRIPTION OF THE DRAWINGS

FIG. 1 is a schematic illustration of a display incorporating MIM devices according to one exemplary embodiment.

FIG. 2 is a schematic illustration of a single MIM device according to one exemplary embodiment.

FIG. 3 is a schematic illustration of a dual MIM device according to one exemplary embodiment.

FIG. 4 is a top plan view of a MIM backplane according to one exemplary embodiment.

FIG. 5 is a sectional view schematically illustrating coupling of an embossing layer and a metal layer upon a carrier substrate according to one exemplary embodiment.

FIG. 6 is a sectional view schematically illustrating embossing or imprinting of at least the embossing layer according to one exemplary embodiment.

FIG. 7A is a sectional view schematically illustrating the imprinted embossing layer having a formed channel according to one exemplary embodiment.

FIG. 7B is a top plan view of the layer of FIG. 7A according to one exemplary embodiment.

FIG. 8A is a sectional view illustrating exposing of the metal layer through the channel according to one exemplary embodiment.

FIG. 8B is a top plan view of the layer of FIG. 8A according to one exemplary embodiment.

FIG. 9A is a sectional view illustrating removal of portions of the metal layer through the channel according to one exemplary embodiment.

FIG. 9B is a top plan view of the layers of FIG. 9A according to one exemplary embodiment.

FIG. 10A is a sectional view schematically illustrating anodization of side edges of the metal layer to form non-linear dielectric portions according to one exemplary embodiment.

FIG. 10B is a top plan view of the layers of FIG. 10A according to one exemplary embodiment.

FIG. 11A is a sectional view schematically illustrating deposition of a metal portion between the non-linear dielectric portions according to one exemplary embodiment.

FIG. 11B is a top plan view of the layers of FIG. 11A according to one exemplary embodiment.

FIG. 12A is a sectional view schematically illustrating removal of portions of the embossing layer to further expose portions of the metal layer according to one exemplary embodiment.

FIG. 12B is a top plan view of the layers of FIG. 12A according to one exemplary embodiment.

FIG. 13A is a sectional view schematically illustrating removal of exposed portions of the metal layer according to one exemplary embodiment.

FIG. 13B is a top plan view of the layers of FIG. 13A according to one exemplary embodiment.

FIG. 14 is a sectional view schematically illustrating further removal of the embossing layer according to one exemplary embodiment.

FIG. 15 is a sectional view schematically illustrating coupling of a display substrate according to one exemplary embodiment.

FIG. 16 is a sectional view schematically illustrating separation of the carrier substrate from the metal layer and the display substrate according to one exemplary embodiment.

FIG. 17 is a sectional view schematically illustrating electrically coupling of an electrode to the metal layer according to one exemplary embodiment.

FIG. 18 is a sectional view schematically illustrating coupling of electro-optical media to the formed backplane to form a display according to one exemplary embodiment.

### DETAILED DESCRIPTION OF THE EXAMPLE EMBODIMENTS

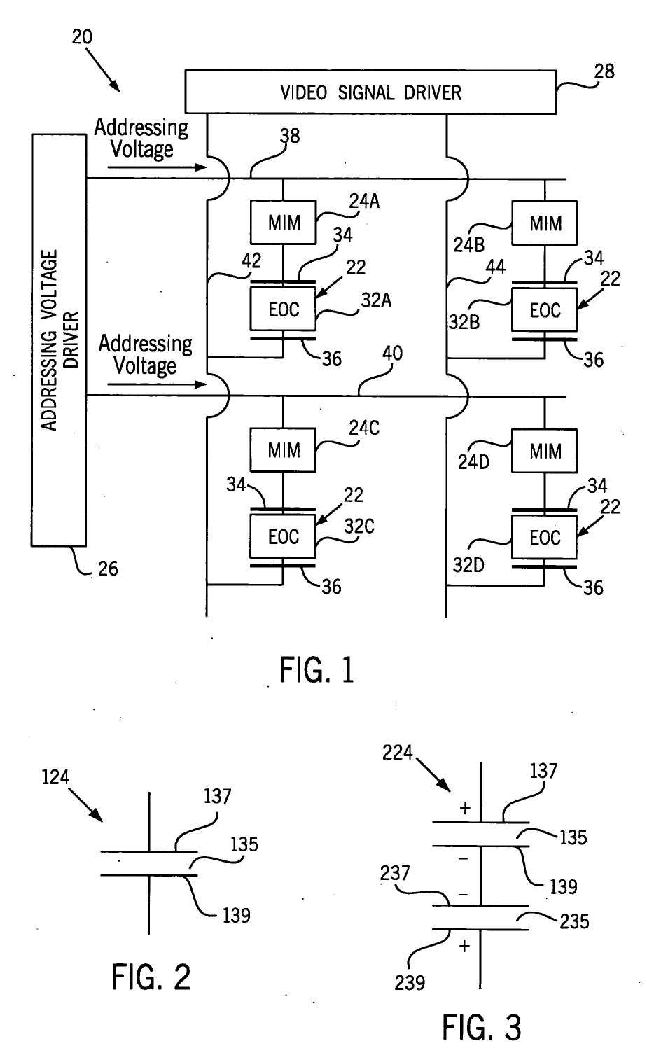

FIG. 1 is a schematic illustration of a display 20 which is shown as an active matrix electro-optical display. Display 20 generally includes electro-optical cells 22, MIM devices 24, addressing voltage driver 26, and video signal driver 28. Electro-optical cells 22 comprise individual cells arranged in a matrix or array and configured to alter or block the transmission of light to produce a visual display or image. Each cell 22 forms a pixel of display 20. Electro-optical cells 22 each generally includes an electro-optical media 32 which is configured to change light altering or blocking states in response to applied electrical charge or electrical fields. In the particular example shown, electro-optical media 32 includes liquid crystals. Each cell 22 additionally includes a pair of electrodes 34, 36 in which the electro-optical media 32 is sandwiched. In a transmissive display where a backlight is implemented, both electrodes 34 and 36 are transparent. In a reflective display, on the other hand, the electrode 36 is transparent while the electrode 34 is reflective. Electrodes 34, 36 apply an electrical field to electro-optical media 32 to selectively vary and control the light-altering or blocking nature or state of electro-optical media 32 and of cell 22.

MIM devices 24 can be either a single MIM device or a dual MIM device that comprises two connected single MIM devices. Each single MIM device includes a non-linear dielectric material sandwiched between a pair of electrically conductive metals. FIG. 2 schematically illustrates a single MIM device 124 which includes a non-linear dielectric 135 sandwiched between a pair of electrically conductive metals 137, 139. Because of the non-linear current/voltage characteristic, current does not flow before a threshold voltage is exceeded. Once the threshold voltage is exceeded, the MIM device presents relatively low impedance. The threshold voltage is observed in both applied polarities. Thus, the MIM devices serve as switches for selectively charging their associated electro-optical cells to produce a desired visual display. It should be noted that if the conductive metals 137 and 139 have different work functions or the interface of metal 137 and dielectric 135 is electronically different from the interface of dielectric 135 and metal 139, the single MIM device may have different threshold voltages in forward and reverse bias. Such a voltage difference may cause undesirable effects in displayed image and requires corrections in driver electronics.

FIG. 3 schematically illustrates a dual MIM device 224 which generally comprises two connected single MIM devices. In particular, dual MIM device 224 includes non-linear dielectric materials 135 and 235 sandwiched between electrically conductive metals 137, 139 and electrically conductive metals 237, 239, respectively. As further shown by FIG. 3, the two single MIM elements or diodes are coupled in an “anti-series” arrangement such that electrically conductive metals of the same work-function are coupled to one another. In the particular example shown, the electrically conductive metals 139 and 237, having the same work function and interface to the dielectric 135 and 236 respectively, are connected together. The electrically conductive metals 137 and 239 also have the same work function and interface to the dielectric 135 and 236, respectively. This configuration provides an ability to cancel out the forward bias effects of one MIM device with the reverse bias effects of another MIM device. Dual MIM device 224 also has a reduced capacitive coupling.

Addressing voltage driver 26 comprises an electronic component configured to transmit electrical voltages to MIMs 24 via addressing lines 38, 40 as shown in FIG. 1. The addressing voltages transmitted by driver 26 represent “select” and “non-select” conditions to switch each MIM device 24 between an electrically conducting state and a non-conducting state. In one embodiment, the addressing voltages transmitted via address lines 38 and 40 may be in the form of a square wave. When the “select” condition is met, a particular MIM device 24 is turned into an electrically conducting state and its associated electro-optical material 32 may be charged based upon video signals from driver 28. Alternatively, when the “non-select” condition is met, a particular MIM device 24 is turned into a non-conducting state and its associated electro-optical media 32 is not charged or addressed by video signals from driver 28.

Video signal driver 28 comprises an electronic component configured to transmit video signals, in the form of electrical voltages, to electro-optical media 32 via video signal lines 42, 44. The video signals transmitted by driver 28 charge the electro-optical media 32 of those cells 22 that are being addressed, resulting from the associated MIM 24 being actuated to a conducting state by driver 26.

In operation according to one scenario, addressing voltage driver 26 transmits a “select” voltage to MIMs 24A and 24B via line 38 and at the same time a “non-select” voltage to MIMs 24C and 24D via line 40. As a result, MIMs 24A and 24B are actuated to conductive states, allowing electro-optical media 32A and 32B to be addressed by video signals transmitted from driver 28 via lines 42 and 44, respectively. The video signals transmitted via lines 42 and 44 may be the same or distinct from one another depending upon the display to be created.

Thereafter, addressing voltage driver 26 may transmit a “non-select” voltage to MIMs 24A and 24B via line 38 and at the same time a “select” voltage to MIMs 24C and 24D via line 40. As a result, MIMs 24C and 24D are actuated to conductive states, allowing electro-optical media 32C and 32D to be addressed and charged in response to receiving video signals from video signal driver 28 via lines 42 and 44, respectively. Once again, the video signals being transmitted via lines 42 and 44 may be the same or may be different depending upon the image being created. Upon being charged, electro-optical media 32A, 32B, 32C and 32D hold their respective states as other cells 22 and electro-optical media 32 are addressed. This process is generally repeated until an entire matrix or array of cells 22 is addressed and actuated to achieve a desired optical output.

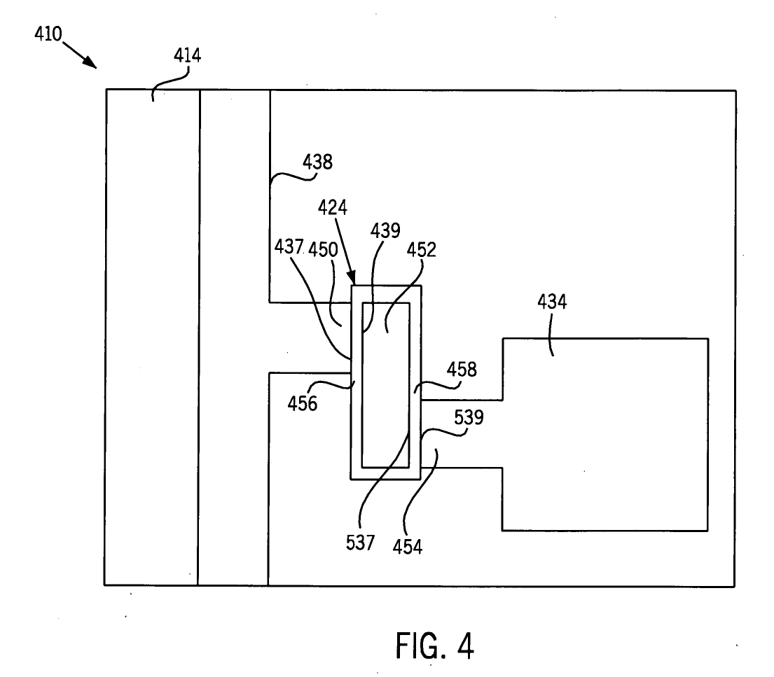

FIG. 4 is a top plan view of one example of a MIM backplane 410 for an individual pixel of a display such as display 20. Backplane 410 includes display substrate 414, the addressing voltage bus line 438, dual MIM device 424, and electrode 434. Display substrate 414 generally comprises a structure supporting the bus line 438, dual MIM device 424, and electrode 434. Substrate 414 is generally formed from dielectric material such as glass or a flexible plastic or polymer. Examples of a flexible plastic or polymer that may be used include polyethylene terephthalate (PET) or polyethylene naphthalate (PEN). In other embodiments, one or more other materials may be used for forming substrate 414. Substrate 414 is generally adhered or bonded to the bus line 438, dual MIM device 424, and electrode 434 by an adhesive such as NOA 81 by Norland Products, Inc. In the particular example shown, substrate 414 has a thickness of between about 50 micrometers and 200 micrometers. The thickness of the adhesive layer extending between substrate 414 and the remaining components of backplane 410 is between about 5 micrometers and 20 micrometers. In other embodiments, the bus line 438, dual MIM device 424, and electrode 434 may be coupled to substrate 414 in other fashions without the use of adhesive.

The bus line 438 comprise electrically conductive traces or lines electrically coupled to addressing voltage driver 26 (shown in FIG. 1). Bus line 438 is electrically coupled to MIM device 424. The line 438 transmits the addressing voltages from driver 26 to MIM devices 424 to actuate or bias such a MIM device between conducting and non-conducting states.

In the particular embodiment shown in FIG. 4, the MIM device 424 is a dual-MIM devices, such as the dual-MIM device 224 schematically shown in FIG. 3. MIM device 424 is electrically connected between bus line 438 and electrode 434 and includes conductive metal portions 450, 452, 454 and non-linear dielectric portions 456 and 458. Metal portions 450 and 452 have boundary areas 437 and 439 between which is sandwiched non-linear dielectric 456. Conducting metal portion 452 and 454 have boundary portions 537 and 539 which are both in contact with non-linear dielectric 458. Metal portion 450 is in electrical contact with address bus line 438. Metal portion 454 is in electrical contact with electrode 434. Upon the transmission of a “select” voltage to MIM device 424, non-linear dielectrics 456 and 458 become electrically conductive, allowing current to flow with little impedance through MIM device 424 to electrode 434. Thus the MIM device 424 serves as a switch, enabling electrode 434 and the associated electro-optical material 32 (shown in FIG. 1) to be selectively addressed depending upon the addressing voltage transmitted via the bus line 438.

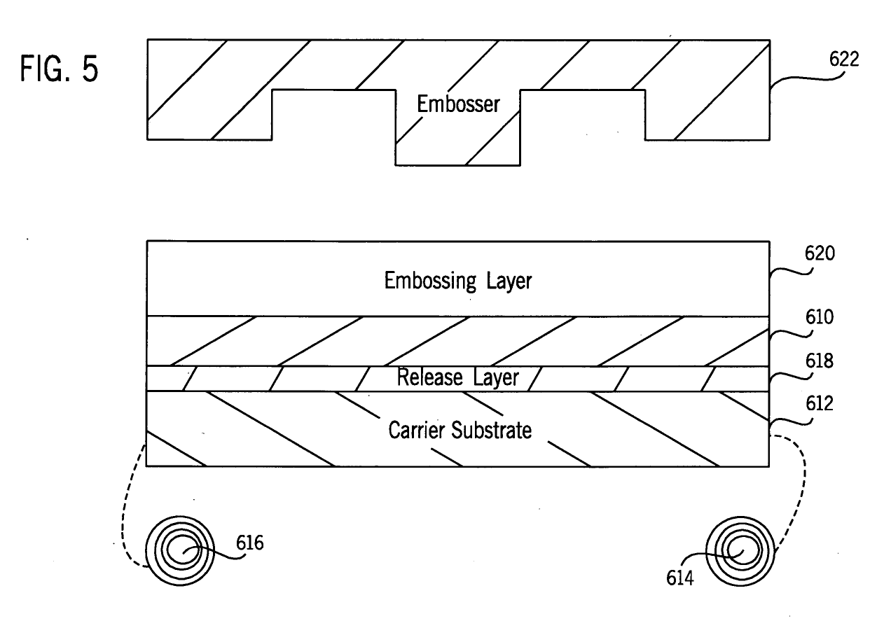

FIGS. 5-17 illustrate a method or process for fabricating the dual MIM backplane 410 (shown in FIG. 4). It should be noted that fabrication of a dual select diode (DSD) based backplane can be also performed using substantially the same process. For example, the other set of MIM devices and the busline can be concurrently formed to the right side of electrode 434 (shown in FIG. 4) during the fabrication of the set of MIM and busline at the left side of the electrode 434.

As shown by FIG. 5, a blanket metal layer 610 is deposited over a carrier substrate 612. Metal layer 610 includes one or more metals that may be treated, such as by anodization, to form a non-linear dielectric material. Examples of materials for metal layer 610 include tantalum, niobium, titanium, copper, silver, aluminum, and their alloys. In the particular example shown, metal layer 610 comprises tantalum. The tantalum metal of layer 610 may be deposited by using physical vapor deposition techniques such as thermal evaporation or sputtering. The tantalum material of layer 610 may also be deposited by electro-forming, wherein the carrier substrate 612 is electrically conductive and is used as an electrode and wherein the tantalum metal is provided by an electrolyte such as a mixture of TaCl₅ and 1-methyl-3 ethlyimidazolium chloride. In other embodiments, other deposition techniques such as chemical vapor deposition may also be used for depositing or applying metal layer 610 over carrier substrate 612.

Carrier substrate 612 comprises an electrically conductive substrate configured to support metal layer 610. In the example shown, carrier substrate 612 is provided as part of a roll-to-roll process, wherein carrier substrate 612 is wrapped about the reels 614, 616. A carrier substrate may be formed from one or more conductive materials such as copper or nickel With a highly smooth surface finish and high conductivity. Carrier substrate 612 may comprise a bulk conductor, such as a metal plate or sheet, or may comprise a dielectric sheet with a conducting surface layer. According to one exemplary embodiment, carrier substrate 612 is passivated to form a thin release layer 618. For example, the conducting surface of carrier substrate 612 is formed from a metal such as copper or nickel and is passivated by treating the surface with 0.1 N potassium dichromate aqueous solution for 10 minutes, followed by rinsing and drying to form release layer 618. Release layer 618 may be a very thin oxide, a surfactant layer or a mono layer polymer release agent. Release layer 618 is substantially conductive. In those embodiments including release layer 618, metal layer 610 is formed upon the release layer 618.

As further shown by FIG. 5, an embossing layer 620 is deposited upon metal layer 610. Embossing layer 620 comprises a layer of one or more materials such that the layer may be embossed or imprinted upon by an embosser such as an embossing shim 622.

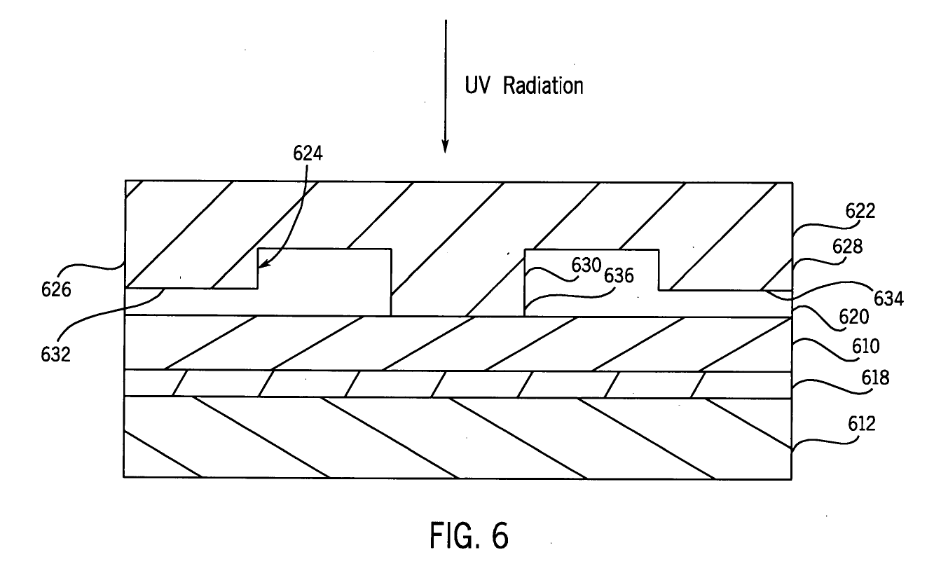

FIG. 6 illustrates the embossing or imprinting upon of embossing layer 620 by embosser 622. As shown by FIG. 6, embosser 622 includes a relief surface 624. Relief surface 624 is configured to form features within embossing layer 620 corresponding to address line 438 and MIM device 424. In the particular example shown, release surface 624 includes projections 626, 628 and 630. Projection 626 forms a channel 632 within embossing layer 620 which generally corresponds to the outline of address line 438 and metal portion 450. Projection 628 embosses or imprints a channel 634 within layer 620 which generally corresponds to the outline or shape of metal portion 454. Projection 630 is configured so as to project into layer 620 so as to form channel 636 which generally has a shape or outline of the boundaries 439, 537 between metal portion 450 and metal portion 454 as shown in FIG. 4.

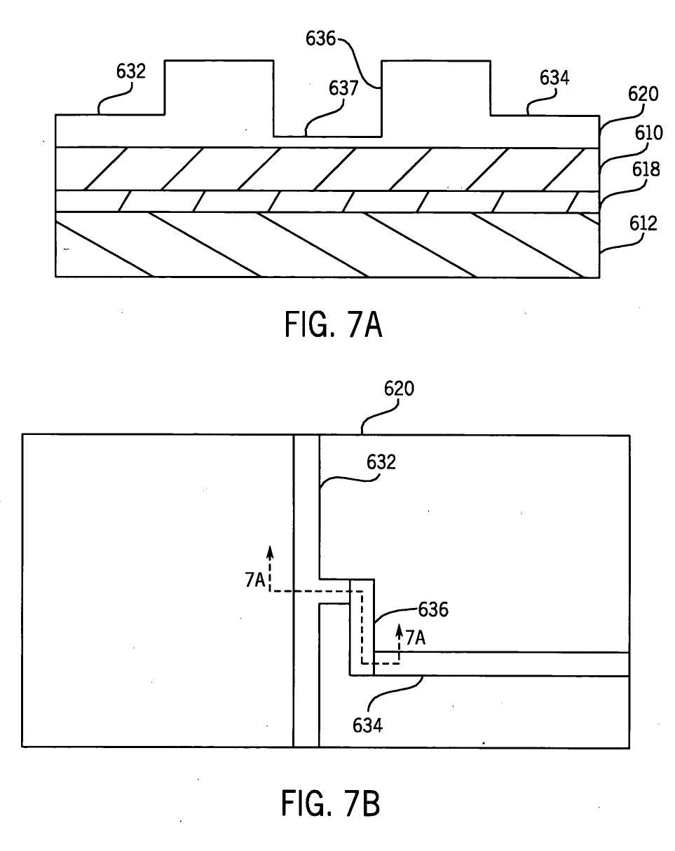

In the particular example shown, embossing layer 620 is formed from one or more materials such that embossing layer 620 has a deformable shape until further processing or solidification. In the particular example shown, embossing layer 620 comprises an optically transparent UV curable dielectric resin (e.g., Norland Optical Products NOA83H). As a result, upon the application of UV illumination, the shape of embossing layer 620 becomes stabilized. In the particular example shown, embosser 622 is substantially transparent to UV wavelengths. Once embosser 622 has been positioned into layer 620 such that layer 620 takes up the form or shape of release surface 624 as shown in FIG. 6, UV illumination is applied through embosser 622 to embossing layer 620 to cure and solidify or stabilize the shape of embossing layer 620 while embosser 622 is in place. Thereafter, as shown in FIGS. 7A and 7B, embosser 620 is separated from layer 620 to expose and reveal channels 632, 634 and 636.

In other embodiments, embossing layer 620 may comprise one or more other materials such that embossing layer 620 may be treated to stabilize the shape of embossing layer 620 by other means such as by heat, chemical thermosetting reactions, microwave radiation or other forms of electromagnetic radiation and the like, while embosser 622 is positioned into layer 620 or upon removal of embosser 622 from layer 620. In still other embodiments, embossing layer 620 may be provided by other materials which do not require treatment to achieve a stabilized shape or which require treatment to achieve a deformable state which naturally stabilizes and shapes over time or which may require further treatment for shape stabilization. Although in the particular example illustrated, embossing layer 620 is formed from one or more transparent materials, in other embodiments, embossing layer 620 may alternatively be opaque such as in those embodiments in which at least those portions of embossing layer 620 which overlie or underlie electro-optical media 32 (shown in FIG. 1) are removed during the manufacture of the display in which backplane 410 is to be used.

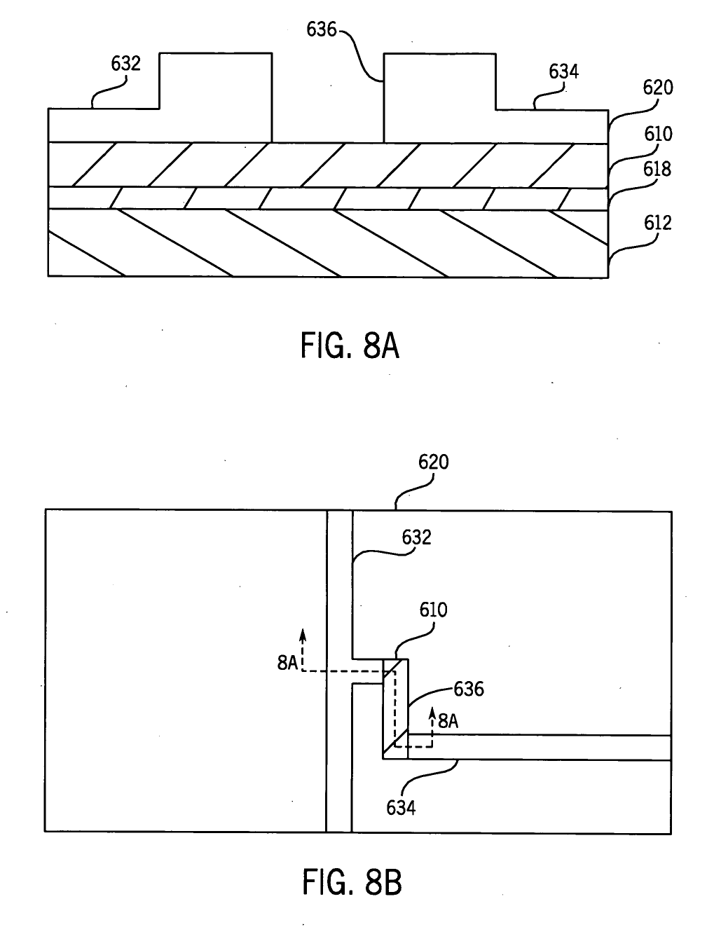

FIGS. 8A and 8B illustrate further deepening of channel 636 so as to expose metal layer 610. In particular, floor 637 (shown in FIG. 7A) of channel 636 is removed. In particular applications, underlying portions of metal layer 610 may also be removed with floor 637. Examples of methods that may be used to remove floor 637 so as to deepen channel 636 and expose layer 610 include oxygen plasma etching, UV-ozone treatment, and laser ablation. In particular applications, the embossing or imprinting of layer 620 may be performed such that channel 636 omits a floor 637 and exposes layer 610.

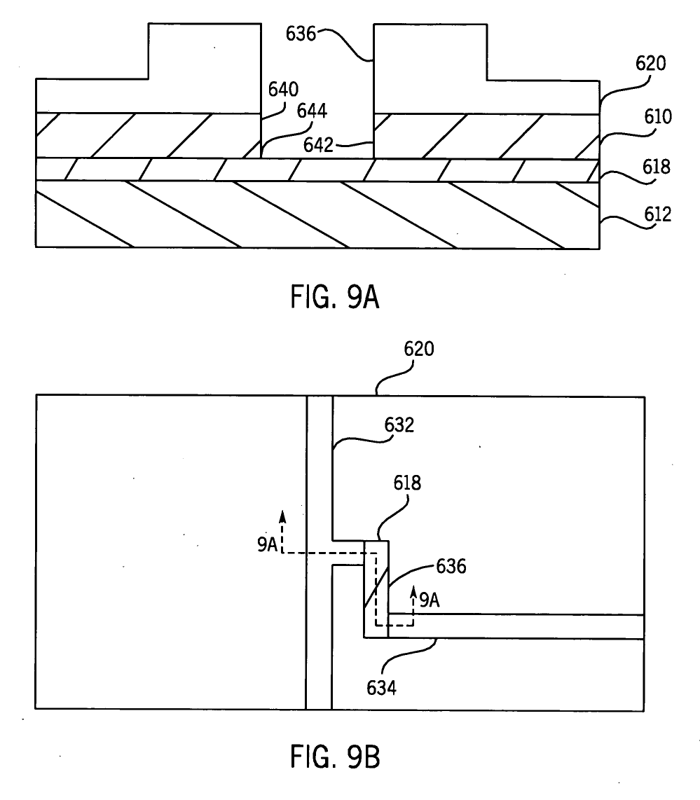

FIGS. 9A and 9B illustrate backplane 410 after portions of metal layer 610 have been removed through channel 636 to further deepen channel 636 and to form recess 640 within layer 610. As a result, layer 610 includes two opposite mutually facing side edges 642, 644. In one embodiment, removal of the metal layer 610 is achieved by a dry or wet etching process. In other embodiments, other material removal techniques may be employed. Should the removal of those portions of layer 610 to form recess 640 result in the removal of release layer 618 or renders release layer 618 ineffective, release layer 618 may be re-passivated (i.e., re-applied) at this stage.

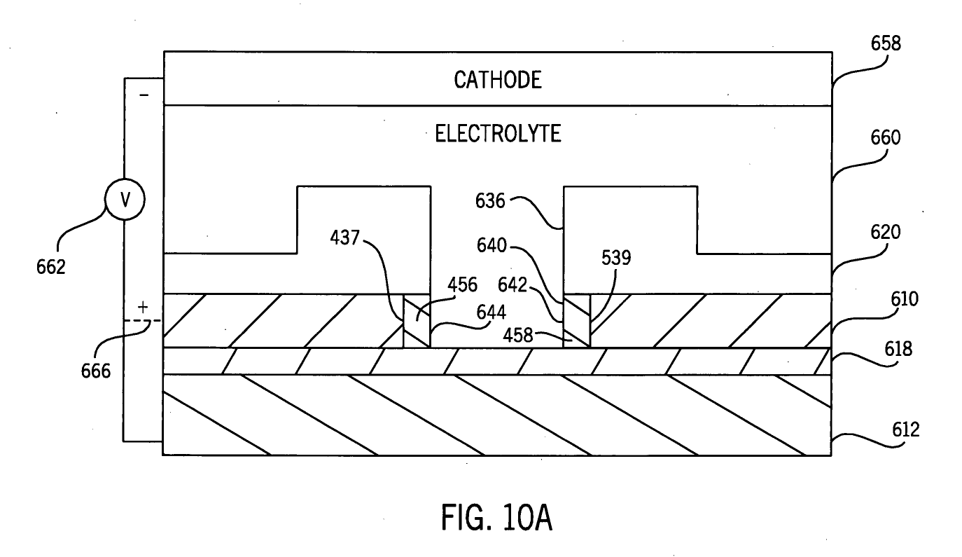

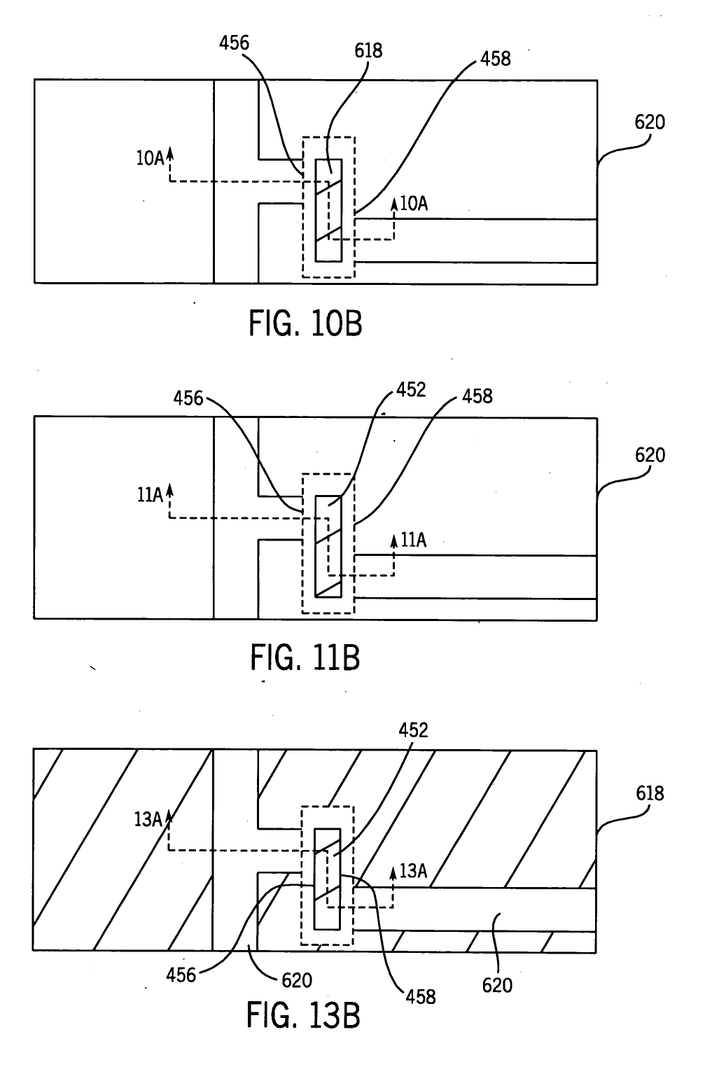

FIGS. 10A and 10B illustrate forming non-linear dielectric portions 456 and 458 along side edges 642 and 644 of metal layer 610 through channel 636. In the particular example shown, side edges 642, 644 of metal layer 610 are anodized to oxidize portions of metal layer 610 proximate to side edges 642 and 644. According to one exemplary embodiment in which metal layer 610 comprises tantalum, the tantalum material adjacent to side edges 642 and 644 is oxidized to form Ta₂O₅, a non-linear dielectric material. The non-linear dielectric portions 456 and 458 are bordered by side edges 642, 644 (which will form boundaries 439 and 537 shown in FIG. 4) and boundaries 437 and 539 which are those regions of metal layer 610 where oxidized portions and non-oxidized portions of metal layer 610 meet.

As shown by FIG. 10A, side edges 642 and 644 of metal layer 610 are anodized using a galvanic cell made up of electrically conductive substrate 612 as an anode, a cathode 658 of a suitable material (e.g., platinum) and a suitable electrolyte 660. In the particular example shown, electrolyte 660 comprises an aqueous solution of 0.01 weight percent citric acid and 0.1 volume percent of ethylenglucol. In other embodiments, other electrolytes may be used such as boric acid solution with the pH adjusted to 7 by NH₄OH, ammonium tartrate, or ammonium borate or other suitable compound. Electrolyte 660 may also include surfactants and buffer materials.

In the particular example shown in which metal layer 610 comprises tantalum having an anodization coefficient of approximately 1.9 nm/volt, voltage source 662 is configured to provide a starting current density of approximately 0.2 mA/cm². The final anodization is performed using a potentiostatic technique wherein the applied voltage is held constant. The applied voltage from voltage source 662 and the time that the anodization is performed at constant voltage determines the thickness of non-linear dielectric portions 456 and 458 and the eventual voltage threshold of MIM device 424 (shown in FIG. 4). According to one exemplary embodiment, voltage source 662 supplies a constant voltage of approximately 35 volts for 30 minutes at the final stage which results in non-linear dielectric portions 456 and 458 having thicknesses of approximately 65 nm. In other embodiments, voltage source 662 may be configured to apply other voltages such that non-linear dielectric portions 456 and 458 have other thicknesses.

In other embodiments, the galvanic cell used for anodizing side edges 642 and 644 of metal layer 610 may be provided by other arrangements. For example, as shown by electrical connection line 666, metal layer 610 may alternatively, or in addition, be utilized as an anode for the galvanic cell. In other embodiments, in lieu of forming non-linear dielectric portions 456 and 458 by altering side edges 642 and 644 of metal layer 610, non-linear dielectric portion 456 and 458 may alternatively be formed by depositing non-linear dielectric material along side edges 642 and 644 within recess 640 or by depositing additional metal material along side edges 642 and 644 within recess 640 and oxidizing the added metal material. Because the non-linear dielectric portions 456 and 458 are formed along side edges 642 and 644 which generally extend perpendicular to a major dimensional surface of metal layer 610, the height of non-linear dielectric portions 456 and 458 may be precisely controlled. In particular embodiments, non-linear dielectric portions 456 and 458 may be controlled so as to have a height of less than 2 micrometers. In some embodiments, the height of non-linear dielectric portions 456 and 458 may be precisely controlled to have a height on the order of nanometers. As a result, backplane 410 may have a reduced overall size.

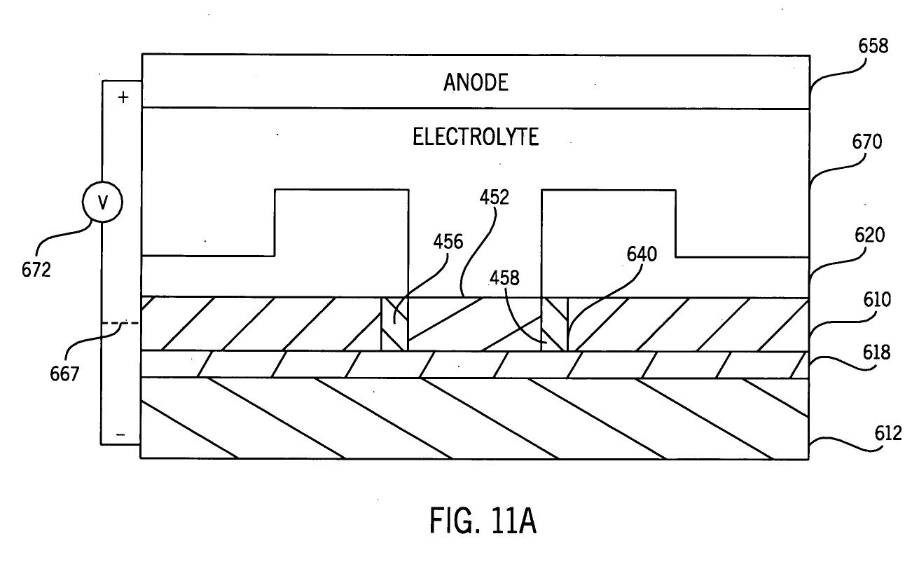

FIGS. 11A and 11B illustrate the forming of metal portion 452 within recess 640 such that metal portion 452 contacts and spaces apart non-linear dielectric portions 456 and 458. In the particular example shown, metal portion 452 is deposited or formed by electroforming or electroplating. In the example shown, such electroplating is done using electrically conductive carrier substrate 612 as a cathode, an anode 658 of a suitable metal, such as platinum or nickel, electrolyte 670 and a voltage source 672. In other embodiments, as indicated by broken line 667, layer 610 may be used as a cathode where the voltage being applied is greater than the threshold voltage of non-linear dielectric portions 456, 458. In the particular example shown in which electro-deposition is used to deposit metal portion 452, metal portion 452 comprises one or more metals or alloys thereof that are capable of electrochemical deposition with good conductivity such as nickel, copper, gold or silver. In the example shown, metal portion 452 has approximately the same thickness as metal layer 610. The metal layer 452 can also be thicker than the metal layer 610 to compensate the possible material loss during etching of the embossing layer 620 and metal layer 610 in the next two steps. In other embodiments, other macro-area deposition techniques may be utilized to deposit metal portion 452.

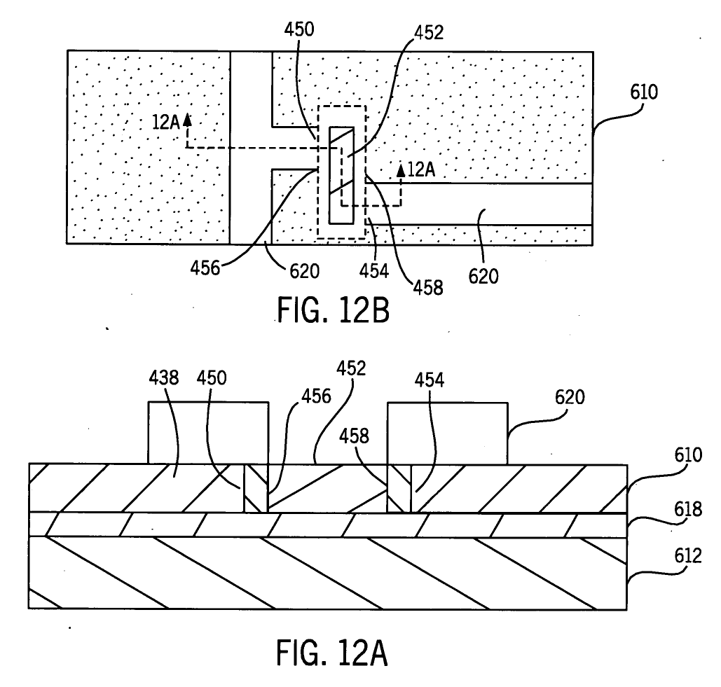

FIGS. 12A and 12B illustrate removal of portions of embossing layer 620 to expose underlying portions of metal layer 610. The remaining portions of embossing layer 620 cover or overlie address bus bar line 438 (shown in FIG. 12A), metal portion 450 and metal portion 454 as shown in FIG. 12A. In the particular example shown, portions of embossing layer 620 are removed by etching. In other embodiments, other macro-area material removal techniques such as oxygen plasma etching, UV-ozone treatment or laser ablation may be utilized to remove portions of embossing layer 620.

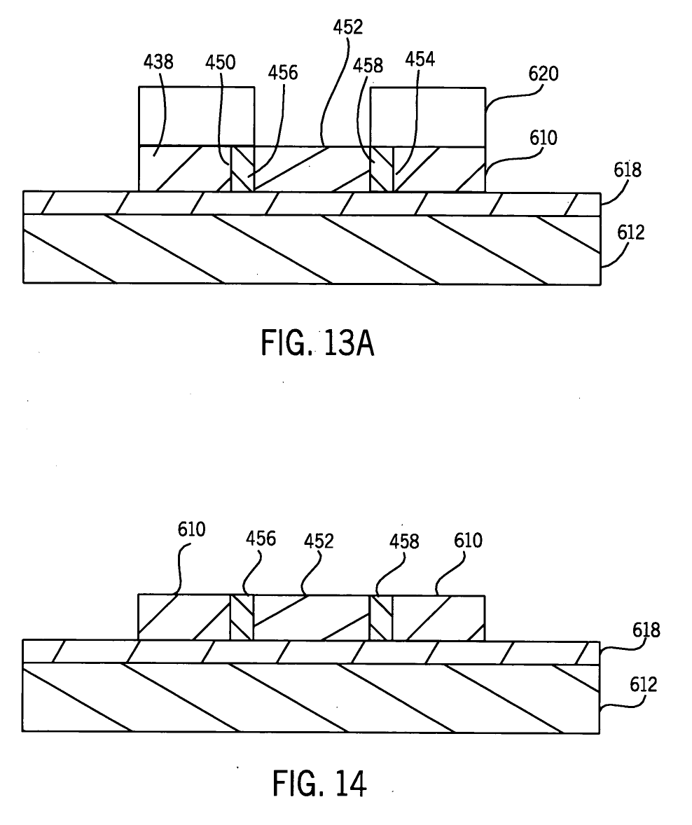

FIGS. 13A and 13B illustrate further removal of exposed portions of metal layer 610. In the particular example shown, those portions of layer 610 which are not protected and covered by embossing layer 620 are removed using a typical dry or wet etching process. As shown by FIG. 13B, those remaining portions of metal layer 610 below layer 620 form address bus bar 438 (shown in FIG. 13A), metal portion 450 and metal portion 454. The processes that may be used to remove the exposed and unprotected portions of metal layer 610 include dry and wet etching. According to one embodiment, the etching method chosen should be such that a large difference in etch rate exists between those exposed portions of metal layer 610 and non-linear dielectric portions 456 and 458. The etching method should also be chosen such that the etch rate of metal portion 452 is relatively low as compared to the etch rate of the exposed portions of metal layer 610 if the thickness of metal 452 is close to the thickness of metal 610.

FIG. 14 illustrates the optional removal of the remaining embossing material of layer 620. Examples of processes that may be used to remove the remaining portions of embossing layer 620 include oxygen plasma etching, UV-ozone treatment and laser ablation. In other embodiments, remaining portions of embossing layer 620 may be left intact.

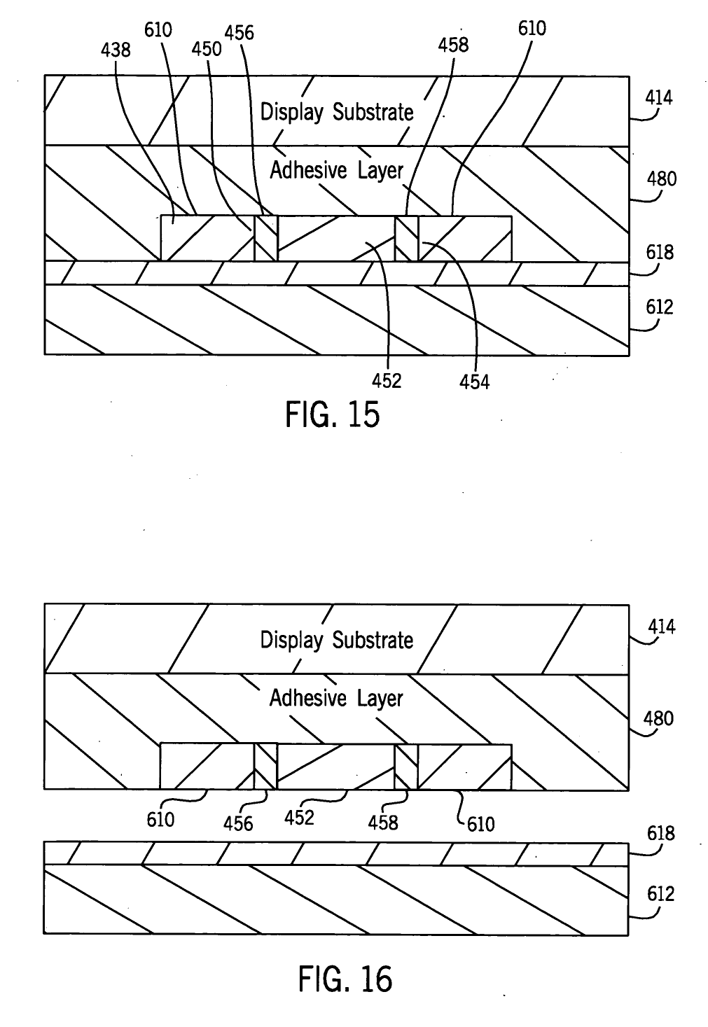

FIG. 15 illustrates coupling of a display substrate to address line 438, metal portion 450, metal portion 454, non-linear dielectric portions 456, 458 and metal portion 452. According to one exemplary embodiment, display substrate 414 is coupled to address line 438 and MIM device 424 by adhesive layer 480. According to one embodiment, adhesive layer 480 has a thickness of between about 5 and 20 micrometers.

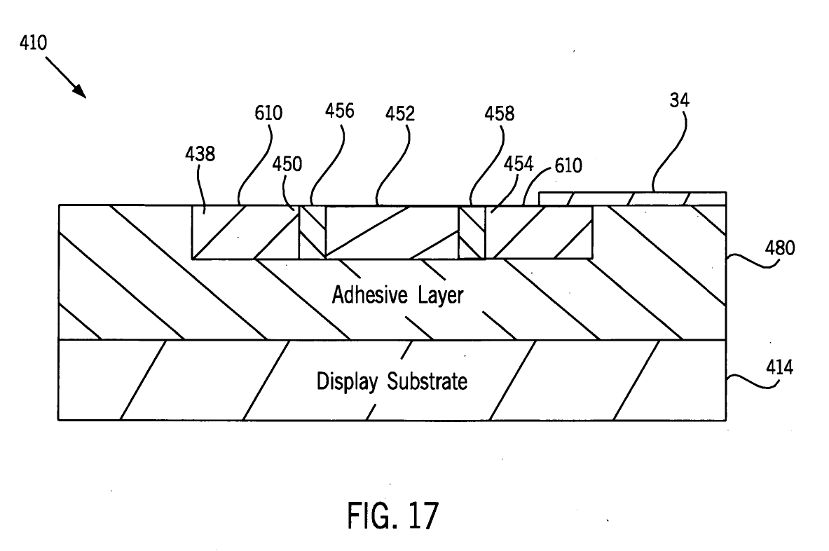

FIG. 16 illustrates separation of carrier substrate 612 and release layer 618. FIG. 17 illustrates the forming of electrode 34. In the particular example shown, electrode 34 is formed by depositing a transparent electrically conductive material in electrical contact with metal portion 454. In one embodiment, electrode 34 is formed from a doped polyethylenedioxythiophene dispersion known as PEDOT or PDOT available as Baytron “P” from Bayer Chemicals. The deposition of electrode 34 may be achieved by any known method such as gravure printing, inkjet deposition or spin-coating, and patterned, utilizing laser patterning or laser ablation or other patterning techniques known in the art.

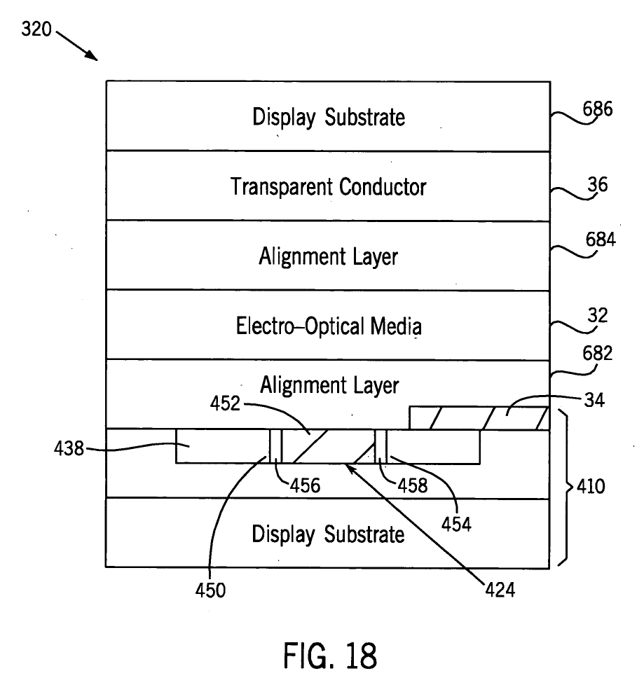

FIG. 18 illustrates further steps towards completing the illustrated portion of display 320 by adding alignment layer 682, electro-optical media 32, alignment layer 684, electrode or transparent conductor 36 and display substrate 686. As a particular example shown by FIG. 18, the electro-optical media 32 comprises liquid crystals and electro-optical media 32 is aligned with the backplane 410 utilizing one or more alignment layers, barrier layers and other applied treatments, collectively represented as alignment layer 682. Electro-optical media 32 is also similarly aligned with display substrate 686 and transparent conductor 36 using one or more alignment layers, barrier layers and other treatments, collectively referred to as alignment layer 684.

Display substrate 686 supports electrode 36 and includes electrode patterning for electrode 36 which may or may not be similar to electrode 34. According to one embodiment, display substrate 686 may be formed in a similar manner to the formation of the metal portion 452 without the steps of anodizing portions of the metal layer to form non-linear dielectrics and without etching of the embossing layer 620. That is, trenches are generated in the embossing layer after application of embosser, metal is then deposited to the trench using the electroplating method to form thin traces lines, and PEDOT is deposited and patterned to form electrodes. In other embodiments, display substrate 686 with electrode patterning may be formed in other manners.

Overall, MIM device 424 has a reduced size while being simpler and less expensive to fabricate. Because MIM device 424 has first and second metal portions and an intermediate non-linear dielectric all formed within a single layer, which has a thickness that can be more precisely controlled, the size of MIM device 424 is reduced. This reduced size enables MIM device 424 to be utilized in more compact electronics such as displays having smaller-sized pixels. Because the fabrication of MIM device 424 is largely achieved using macro-area processing techniques, such as embossing or imprinting, electroplating and the like, the fabrication of MIM device 424 may not require more expensive techniques such as masking and photolithography. As a result, the fabrication of MIM device 424 is simpler and less expensive. In addition, the above-described process enables the simultaneous fabrication of both MIM diodes of a dual MIM device and two or more dual-MIM devices such as in a dual select diode (DSD) configuration in a single layer of a single backplane 410, reducing fabrication costs.

Although backplane 410 has been described as including dual-MIM devices 424 electrically connected to electrode 34, backplane 410 may alternatively include a dual select diode (DSD) configuration connected to an electrode 34. In still other embodiments, backplane 410 may be configured to alternatively include only one single MIM device for use in a display such as display 20. Although backplane 410 has been described as being utilized in a display which utilizes liquid crystals as electro-optical media, backplane 410 and MIM device 424 may alternatively be utilized in other displays using other electro-optical media. Although backplane 410 and MIM device 424 have been illustrated for use in a display, backplane 410 and MIM device 424 may alternatively be configured for use in other electronic applications wherein an electrical switching mechanism, as provided by MIM device 424, is needed.

Although the present invention has been described with reference to example embodiments, workers skilled in the art will recognize that changes may be made in form and detail without departing from the spirit and scope of the invention. For example, although different example embodiments may have been described as including one or more features providing one or more benefits, it is contemplated that the described features may be interchanged with one another or alternatively be combined with one another in the described example embodiments or in other alternative embodiments. Because the technology of the present invention is relatively complex, not all changes in the technology are foreseeable. The present invention described with reference to the example embodiments and set forth in the following claims is manifestly intended to be as broad as possible. For example, unless specifically otherwise noted, the claims reciting a single particular element also encompass a plurality of such particular elements.

1. A metal-insulator-metal device, comprising:
a layer having a major dimensional surface, the layer including:
a first metal portion having a first boundary;
a second metal portion having a second boundary facing the first boundary in a direction parallel to the surface; and
a first non-linear dielectric between the first boundary and the second boundary and having a thickness orthogonal to the major dimensional surface.

2. The device of claim 1, wherein the second metal portion includes a third boundary and wherein the layer further includes:
a third metal portion having a fourth boundary facing the third boundary in a direction parallel to the surface; and
a second non-linear dielectric adjacent the third boundary and the fourth boundary.

3. The device of claim 2, wherein the first boundary and the fourth boundary extend parallel to one another.

4. The device of claim 2, wherein the first non-linear dielectric extends adjacent the surface.

5. The device of claim 2, wherein the layer has a thickness and wherein the surface has at least one dimension greater than the thickness.

6. The device of claim 2, wherein the first non-linear dielectric is an oxide of at least one metal selected from the group of metals consisting of: tantalum, niobium, titanium, copper, silver, aluminum, and alloys thereof.

7. The device of claim 2, wherein the first metal portion includes at least one metal selected from a group of metals including tantalum, niobium, titanium, copper, silver, aluminum, and alloys thereof.

8. The device of claim 7, wherein the first non-linear dielectric comprises an oxide of the metal.

9. The device of claim 2, wherein the third metal portion includes the same metal as the first metal.

10. The device of claim 2 including a single unitary body of metal providing the first metal portion and the first non-linear dielectric.

11. The device of claim 2, wherein the device is part of a display including:
electro-optical media electrically connected to one of the first metal portion and the third metal portion.

12. The device of claim 2, wherein the first non-linear dielectric is formed by oxidizing a first side edge of the first metal portion and wherein the second metal portion is formed adjacent the first side edge.

13. The device of claim 12, wherein the second non-linear dielectric is formed by oxidizing a second side edge of the third metal portion and wherein the second metal portion is formed adjacent the second side edge.

14. The device of claim 1, wherein the layer has a thickness and wherein the surface has at least one dimension greater than the thickness.

15. The device of claim 1, wherein the first non-linear dielectric is an oxide of at least one metal selected from the group of metals consisting of: tantalum, niobium, titanium, copper, aluminum, silver, and alloys thereof.

16. The device of claim 1, wherein the first metal portion includes at least one metal selected from a group of metals including tantalum, niobium, titanium, copper, silver, aluminum, and alloys thereof.

17. The device of claim 15, wherein the first non-linear dielectric comprises an oxide of the metal.

18. The device of claim 1 including a single unitary body of metal providing the first metal portion and the first non-linear dielectric.

19. The device of claim 1, wherein the device is part of a display including:
electro-optical media electrically connected to the one of first metal portion and the second metal portion.

20. The device of claim 1, wherein the first non-linear dielectric extends adjacent the surface.

21. The device of claim 1, wherein the first non-linear dielectric is formed by oxidizing a first side edge of the first metal portion and wherein the second metal portion is formed adjacent the first side edge.

22. A display, comprising:
electro-optical media; and
a layer having a major dimensional surface and including:
a first metal portion having a first boundary, the first metal portion being electrically connected to the electro-optical media;
a second metal portion having a second boundary facing the first boundary in a direction parallel to the surface; and
a first non-linear dielectric between the first boundary and the second boundary and having a thickness orthogonal to the surface.

23. The display of claim 22, wherein the second metal portion includes a third boundary and wherein the layer further includes:
a third metal portion having a fourth boundary facing the third boundary in a direction parallel to the surface; and
a second non-linear dielectric adjacent the third boundary and the fourth boundary.

24. The display of claim 22, wherein the electro-optical media includes liquid crystals.

25. The display of claim 22 including a first electrode electrically connected to one of the first metal portion and the second metal portion.

26. The display of claim 25 including a second electrode opposite the first electrode.

27. The display of claim 22, wherein the first non-linear dielectric extends adjacent the surface.

28. The display of claim 22, wherein the layer has a thickness and wherein the surface has at least one dimension greater than the thickness.

29. The display of claim 22, wherein the first non-linear dielectric is an oxide of at least one metal selected from the group of metals consisting of: tantalum, niobium, titanium, copper, silver, aluminum, and alloys thereof.

30. The display of claim 22, wherein the first metal portion includes at least one metal selected from a group of metals consisting of: tantalum, niobium, titanium, copper, silver, aluminum, and alloys thereof.

31. The display of claim 30, wherein the first non-linear dielectric comprises an oxide of the metal.

32. The display of claim 22, wherein the second metal portion includes a third boundary and wherein the layer further includes:
a third metal portion having a fourth boundary facing the third boundary in a direction parallel to the surface; and
a second non-linear dielectric adjacent the third boundary and the fourth boundary and wherein the first metal portion includes a metal and wherein the third metal portion includes the same metal.

33. A method for forming a metal-insulator-metal device, the method comprising:
oxidizing a first side edge of a metal layer to create a first non-linear dielectric along the first side edge adjacent a first metal conducting portion of the layer; and
forming a second metal adjacent the first side edge.

34. The method of claim 33 including:
oxidizing a second side edge of the layer facing the first side edge to create a second non-linear dielectric along the second side edge and adjacent a second metal conducting portion, wherein the second metal is formed adjacent the second side edge.

35. The method of claim 34 including:
anodizing the second side edge to oxidize the second side edge.

36. The method of claim 33 including forming a recess in the metal layer to form the first side edge and the second side edge.

37. The method of claim 36, wherein the step of forming a recess includes:
applying a second layer of material on the metal layer;
imprinting the second layer to form a cavity;
exposing the first layer through the cavity; and
removing a portion of the first layer through the cavity.

38. The method of claim 37, wherein the cavity has a depth of no greater than 2 micrometers.

39. The method of claim 37, wherein the step of removing the portion of the first layer includes etching.

40. The method of claim 37, wherein the step of removing the portion of the second layer includes at least one of oxygen plasma etching, UV ozone treatment and laser ablation.

41. The method of claim 33, wherein the step of forming the second metal conducting portion includes electro-forming.

42. The method of claim 33, wherein the first metal layer includes at least one of tantalum, niobium, titanium, copper, silver, aluminum, and alloys thereof.

43. The method of claim 33, wherein the second metal conducting portion includes at least one of nickel, copper, gold, and silver.

44. The method of claim 33, wherein the first side edge has a height of less than 2 μm.

45. The method of claim 33 including anodizing the first side edge to oxidize the first side edge.

46. A method for forming a display, the method comprising:
anodizing a first side edge of a metal layer to create a first non-linear dielectric along the first side edge adjacent a first metal conducting portion of the layer;
forming a second metal conducting portion adjacent the first side edge; and
electrically connecting one of the first metal conducting portion and the second metal conducting portion to an electro-optical media.

47. The method of claim 46, wherein the step of electrically connecting includes forming a layer of electrically conductive material upon said one of the first metal conductive portion and the second metal conductive portion.

48. The method of claim 47, wherein the electrically conductive material is substantially transparent.

49. The method of claim 46, wherein the electro-optical media includes liquid crystals.

50. A metal-insulator-metal device, comprising:
a layer having a major dimensional surface, the layer including:
a first metal portion having a first boundary perpendicular to the surface;
a second metal portion having a second boundary facing the first boundary;
a first non-linear dielectric between the first boundary and the second boundary having a thickness perpendicular to the first boundary.

51. The device of claim 1, wherein the second metal portion includes a third boundary perpendicular to the surface and wherein the layer further includes:
a third metal portion having a fourth boundary perpendicular to the surface facing the third boundary; and
a second non-linear dielectric between the third boundary and the fourth boundary having a thickness perpendicular to the fourth boundary.

52. A display, comprising:
electro-optical media; and
a layer having a major dimensional surface, the layer including:
a first metal portion having a first boundary perpendicular to the surface;
a second metal portion having a second boundary facing the first boundary;
a first non-linear dielectric between the first boundary and the second boundary having a thickness perpendicular to the first boundary.

53. The display of claim 52, wherein the second metal portion includes a third boundary perpendicular to the surface and wherein the layer further includes:
a third metal portion having a fourth boundary perpendicular to the surface facing the third boundary; and
a second non-linear dielectric between the third boundary and the fourth boundary having a thickness perpendicular to the fourth boundary.

54. The display of claim 52, wherein the second metal portion includes a third boundary perpendicular to the surface and wherein the layer further includes:
a third metal portion having a fourth boundary perpendicular to the surface facing the third boundary; and
a second non-linear dielectric between the third boundary and the fourth boundary having a thickness perpendicular to the fourth boundary and wherein the first metal portion includes a metal and wherein the third metal portion includes the same metal.
